(19) United States
(12) Patent Application Publication
(10) Pub. No.: US 2014/0175459 A1
(43) Pub. Date: Jun. 26, 2014

(54) SILICON CARBIDE SEMICONDUCTOR DEVICE AND METHOD FOR MANUFACTURING THE SAME

(71) Applicants: Kensaku Yamamoto, Chiryu-city (JP); Masato Noborio, Kariya-city (JP); Hideo Matsuki, Obu-city (JP); Hidefumi Takaya, Miyoshi-city (JP); Masahiro Sugimoto, Toyota-city (JP); Narumasa Soejima, Seto-city (JP); Tsuyoshi Ishikawa, Nisshin-city (JP); Yukihiko Watanabe, Nagoya-city (JP)

(72) Inventors: Kensaku Yamamoto, Chiryu-city (JP); Masato Noborio, Kariya-city (JP); Hideo Matsuki, Obu-city (JP); Hidefumi Takaya, Miyoshi-city (JP); Masahiro Sugimoto, Toyota-city (JP); Narumasa Soejima, Seto-city (JP); Tsuyoshi Ishikawa, Nisshin-city (JP); Yukihiko Watanabe, Nagoya-city (JP)

(73) Assignees: TOYOTA JIDOSHA KABUSHIKI KAISHA, Toyota-shi, Aichi-ken (JP); DENSO CORPORATION, Kariya-city, Aichi-pref. (JP)

(21) Appl. No.: 13/994,855

(22) PCT Filed: Feb. 6, 2012
(86) PCT No.: PCT/JP2012/000769

§ 371 Date: Jun. 17, 2013

(30) Foreign Application Priority Data
Feb. 11, 2011 (JP) 2011-027995

(51) Int. Cl. H01L 29/78; H01L 29/16; H01L 29/66

(52) U.S. Cl. CPC H01L 29/7813; H01L 29/66068; H01L 29/1608
USPC 257/77; 438/270

(57) ABSTRACT

A SiC semiconductor device includes: a semiconductor switching element having: a substrate, a drift layer and a base region stacked in this order; a source region and a contact region in the base region; a trench extending from a surface of the source region to penetrate the base region; a gate electrode on a gate insulating film in the trench; a source electrode electrically coupled with the source region and the base region; a drain electrode on a back side of the substrate; and multiple deep layers in an upper portion of the drift layer deeper than the trench. Each deep layer has upper and lower portions. A width of the upper portion is smaller than the lower portion.

### CROSS REFERENCE TO RELATED APPLICATIONS

This application is a U.S. national stage application of International Patent Application No. PCT/JP2012/000769 filed on Feb. 6, 2012 and is based on Japanese Patent Application No. 2011-27995 filed on Feb. 11, 2011, the disclosure of which is incorporated herein by reference.

### TECHNICAL FIELD

The present disclosure relates to a silicon carbide semiconductor device having a trench gate type switching element and a method for manufacturing a silicon carbide semiconductor device.

### BACKGROUND ART

In SiC semiconductor devices, an increase in channel density is effective for providing greater electric current. A MOSFET with a trench gate structure has therefore been adopted and already been put to practical use in silicon transistors. Needless to say, this trench gate structure can be applied to a SiC semiconductor device. A serious problem however occurs when it is applied to SiC. Described specifically, SiC has breakdown field strength ten times that of silicon so that a SiC semiconductor device is used while applying an electric field about ten times that of a silicon device. So, the gate insulating film formed in a trench in SiC is easily broken at a corner of the trench.

In order to overcome this problem, Patent Document 1 proposes a SiC semiconductor device having, below a p type base region, p-type deep layers which are formed in a stripe pattern and cross a trench constituting a trench gate structure. In this SiC semiconductor device, by extending a depletion layer from each of p type deep layers toward an n⁻ type drift layer to prevent application of a high voltage to a gate insulating film, an electric field concentration in the gate insulating film can be mitigated and thereby the gate insulating film can be prevented from being broken.

Although the structure equipped with the p type deep layers as described in Patent Document 1 is effective for preventing an electric field concentration to the gate insulating film, a current path is narrowed by the p type deep layers and a JFET region is formed between two p type deep layers adjacent to each other, resulting in an increase in on-resistance.

### CITATION LIST

### Patent Literature

[PTL 1]
Japanese Patent Laid-Open No. 2009-194065 (corresponding to US 2009/0200559)

### SUMMARY

In view of the above-described problem, it is an object of the present disclosure to provide a silicon carbide semiconductor device having a trench gate type switching element with a low on-state resistance. It is another object of the present disclosure to provide a method for manufacturing a silicon carbide semiconductor device having a trench gate type switching element with a low on-state resistance.

According to a first aspect of the present disclosure, a silicon carbide semiconductor device includes: an inversion type semiconductor switching element. The inversion type semiconductor switching element includes: a substrate having a first or second conductivity type and made of silicon carbide; a drift layer disposed on the substrate, having an impurity concentration lower than the substrate, having the first conductivity type, and made of silicon carbide; a base region disposed on the drift layer, having the second conductivity type, and made of silicon carbide; a source region disposed in an upper portion of the base region, having an impurity concentration higher than the drift layer, having the first conductivity type, and made of silicon carbide; a contact region disposed in another upper portion of the base region, having an impurity concentration higher than the base layer, having the second conductivity type, and made of silicon carbide; a trench extending from a surface of the source region to penetrate the base region and having a first direction as a longitudinal direction; a gate insulating film disposed on an inner wall of the trench; a gate electrode disposed on the gate insulating film in the trench; a source electrode electrically coupled with the source region and the base region; and a drain electrode disposed on a back side of the substrate. The inversion type semiconductor switching element is configured to flow current between the source electrode and the drain electrode via the source region, an inversion type channel region and the drift layer. The inversion type channel region is provided in a portion of the base region positioned on a side of the trench by controlling a voltage applied to the gate electrode. The inversion type semiconductor switching element further includes: a plurality of deep layers having the second conductivity type. Each deep layer is disposed in an upper portion of the drift layer below the base region, has a depth deeper than the trench, and extends along a second direction, which crosses the first direction. Each deep layer has an upper portion and a lower portion. A width of the upper portion is smaller than the lower portion.

In the above device, since the width of the upper portion is smaller than the lower portion, a channel width around the upper portion of the deep layer is expanded when a gate voltage is applied to the gate electrode to form the channel around the upper portion of the deep layer. Thus, a width of a JFET region is wider than a case where a width of the deep layer is constant. In this case, a JFET resistance is reduced, and an on-state resistance is also reduced.

According to a second aspect of the present disclosure, a method for manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a plurality of deep layers having the second conductivity type in a surface portion of the drift layer by implanting an ion on a surface of the drift layer through a first mask after the first mask is formed on the surface of the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the base region via the source region and the contact region; and forming a drain electrode on a back side of the substrate. Each deep layer is disposed in an upper portion of the drift layer below the base region, has a depth deeper than the trench, and extends along a second direction, which crosses the first direction. Each deep layer has an upper portion and a lower portion, and a width of the upper portion is smaller than the lower portion.

In the above method, since the width of the upper portion is smaller than the lower portion, a channel width around the upper portion of the deep layer is expanded when a gate voltage is applied to the gate electrode to form the channel around the upper portion of the deep layer. Thus, a width of a JFET region is wider than a case where a width of the deep layer is constant. In this case, a JFET resistance is reduced, and an on-state resistance is also reduced.

### BRIEF DESCRIPTION OF DRAWINGS

The above and other objects, features and advantages of the present disclosure will become more apparent from the following detailed description made with reference to the accompanying drawings. In the drawings:

FIG. 1 is a perspective cross-sectional view of an inversion type MOSFET having a trench gate structure according to a first embodiment;

FIG. 2A is a cross-sectional view of the MOSFET taken along the line IIA-IIA of FIG. 1;

FIG. 2B is a cross-sectional view taken along the line IIB-IIB of FIG. 1;

FIG. 2C is a cross-sectional view taken along the line IIC-IIC of FIG. 1;

FIG. 2D is a cross-sectional view taken along the line IID-IID of FIG. 1;

FIG. 3 is a partial perspective cross-sectional view of the vicinity of a trench shown while omitting therefrom a gate oxide film, a gate electrode, and the like in a trench gate structure;

FIG. 4A is a cross-sectional view of the MOSFET taken along line IIB-IIB in FIG. 1 showing a manufacturing step of the MOSFET having a trench gate structure shown in FIG. 1;

FIG. 4B is a cross-sectional view of the MOSFET taken along line IID-IID in FIG. 1 showing a manufacturing step of the MOSFET having a trench gate structure shown in FIG. 1;

FIG. 4C is a cross-sectional view of the MOSFET taken along line IIB-IIB in FIG. 1 showing a manufacturing steps of the MOSFET having a trench gate structure shown in FIG. 1;

FIG. 4D is a cross-sectional view of the MOSFET taken along line IID-IID in FIG. 1 showing a manufacturing step of the MOSFET having a trench gate structure shown in FIG. 1;

FIG. 4E is a cross-sectional view of the MOSFET taken along line IIB-IIB in FIG. 1 showing a manufacturing step of the MOSFET having a trench gate structure shown in FIG. 1;

FIG. 4F is a cross-sectional view of the MOSFET taken along line IID-IID in FIG. 1 showing a manufacturing step of the MOSFET having a trench gate structure shown in FIG. 1;

FIG. 5A is a cross-sectional view of the MOSFET taken along line IIB-IIB in FIG. 1 showing a manufacturing step of the MOSFET having a trench gate structure following those of FIGS. 4A, 4C and 4E;

FIG. 5B is a cross-sectional view of the MOSFET taken along line IID-IID in FIG. 1 showing a manufacturing step of the MOSFET having a trench gate structure following those of FIGS. 4B, 4D and 4F;

FIG. 5C is a cross-sectional view of the MOSFET taken along line IIB-IIB in FIG. 1 showing a manufacturing step of the MOSFET having a trench gate structure following those of FIGS. 4A, 4C and 4E;

FIG. 5D is a cross-sectional view of the MOSFET taken along line IID-IID in FIG. 1 showing a manufacturing step of the MOSFET having a trench gate structure following those of FIGS. 4B, 4D and 4F;

FIG. 5E is a cross-sectional view of the MOSFET taken along line IIB-IIB in FIG. 1 showing a manufacturing step of the MOSFET having a trench gate structure following those of FIGS. 4A, 4C and 4E;

FIG. 5F is a cross-sectional view of the MOSFET taken along line IID-IID in FIG. 1 showing a manufacturing step of the MOSFET having a trench gate structure following those of FIGS. 4B, 4D and 4F;

FIG. 6 is a perspective cross-sectional view of a SiC semiconductor device according to a second embodiment;

FIG. 7A is a cross-sectional view taken along the line VIIA-VIIA in parallel with the xz plane in FIG. 6;

FIG. 7B is a cross-sectional view taken along the line VIIB-VIIB in parallel with the yz plane in FIG. 6;

FIG. 8 is a perspective cross-sectional view of a SiC semiconductor device according to a third embodiment;

FIG. 9A is a cross-sectional view taken along the line IXA-IXA in parallel with the xz plane in FIG. 8;

FIG. 9B is a cross-sectional view taken along the line IXB-IXB in parallel with the yz plane in FIG. 8;

FIG. 10A is a cross-sectional view of the MOSFET taken along line IXA-IXA in FIG. 8 showing a manufacturing step of the MOSFET having a trench gate structure shown in FIG. 8;

FIG. 10B is a cross-sectional view of the MOSFET taken along line IXB-IXB in FIG. 8 showing a manufacturing step of the MOSFET having a trench gate structure shown in FIG. 8;

FIG. 10C is a cross-sectional view of the MOSFET taken along line IXA-IXA in FIG. 8 showing a manufacturing step of the MOSFET having a trench gate structure shown in FIG. 8;

FIG. 10D is a cross-sectional view of the MOSFET taken along line IXB-IXB in FIG. 8 showing a manufacturing step of the MOSFET having a trench gate structure shown in FIG. 8;

FIG. 10E is a cross-sectional views of the MOSFET taken along line IXA-IXA in FIG. 8 showing a manufacturing step of the MOSFET having a trench gate structure shown in FIG. 8;

FIG. 10F is a cross-sectional view of the MOSFET taken along line IXB-IXB in FIG. 8 showing a manufacturing step of the MOSFET having a trench gate structure shown in FIG. 8;

FIG. 11A is a cross-sectional view of the MOSFET taken along line IXA-IXA in FIG. 8 showing a manufacturing step of the MOSFET having a trench gate structure following those of FIGS. 10A, 10C and 10E;

FIG. 11B is a cross-sectional view of the MOSFET taken along line IXB-IXB in FIG. 8 showing a manufacturing step of the MOSFET having a trench gate structure following those of FIGS. 10B, 10D and 10F;

FIG. 11C is a cross-sectional view of the MOSFET taken along line IXA-IXA in FIG. 8 showing a manufacturing step of the MOSFET having a trench gate structure following those of FIGS. 10A, 10C and 10E;

FIG. 11D is a cross-sectional view of the MOSFET taken along line IXB-IXB in FIG. 8 showing a manufacturing step of the MOSFET having a trench gate structure following those of FIGS. 10B, 10D and 10F;

FIG. 11E is a cross-sectional view of the MOSFET taken along line IXA-IXA in FIG. 8 showing a manufacturing step of the MOSFET having a trench gate structure following those of FIGS. 10A, 10C and 10E;

FIG. 11F is a cross-sectional view of the MOSFET taken along line IXB-IXB in FIG. 8 showing a manufacturing step of the MOSFET having a trench gate structure following those of FIGS. 10B, 10D and 10F;

FIG. 12 is a perspective cross-sectional view of a SiC semiconductor device according to a fourth embodiment;

FIG. 13A is a cross-sectional view taken along the line XIIIA-XIIIA in parallel with the xz plane in FIG. 12;

FIG. 13B is a cross-sectional view taken along the line XIIIB-XIIIB in parallel with the yz plane in FIG. 12;

FIG. 14 is a perspective cross-sectional view of a SiC semiconductor device according to a fifth embodiment;

FIG. 15A is a cross-sectional view taken along the line XVA-XVA in parallel with the xz plane in FIG. 14; and

FIG. 15B is a cross-sectional view taken along the line XVB-XVB in parallel with the yz plane in FIG. 14.

### DESCRIPTION OF EMBODIMENTS

### First Embodiment

A first embodiment will next be described. Here, an inversion type MOSFET with a trench gate structure will be described as an element equipped in a SiC semiconductor device.

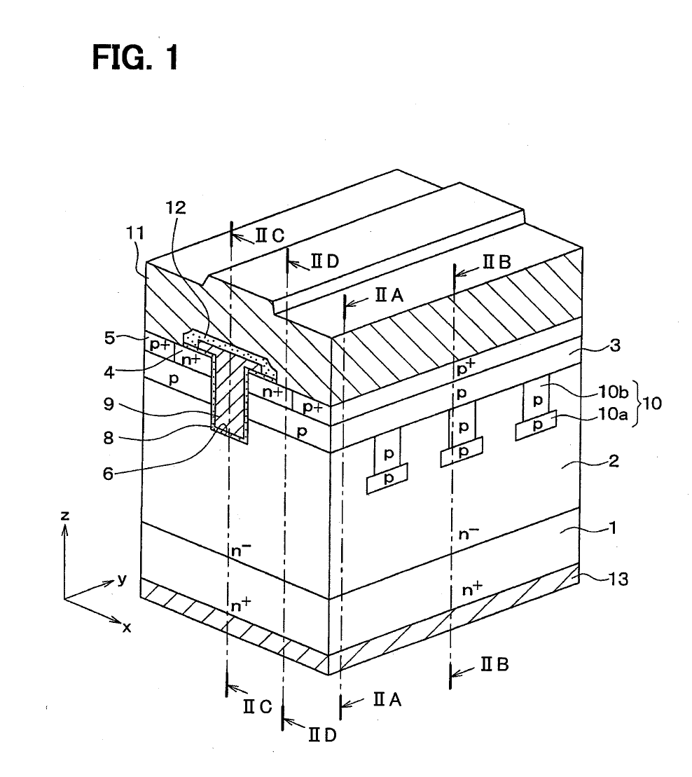

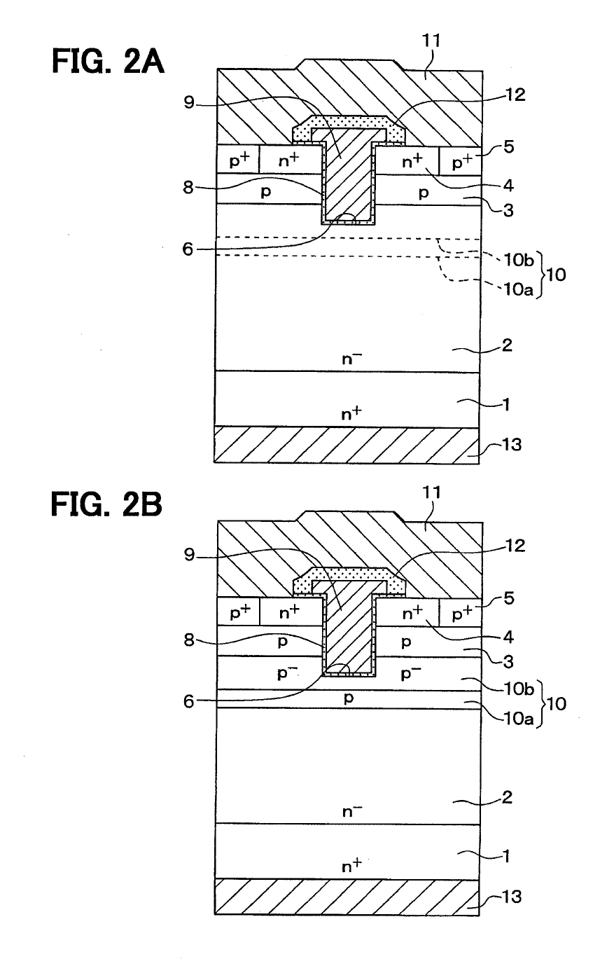

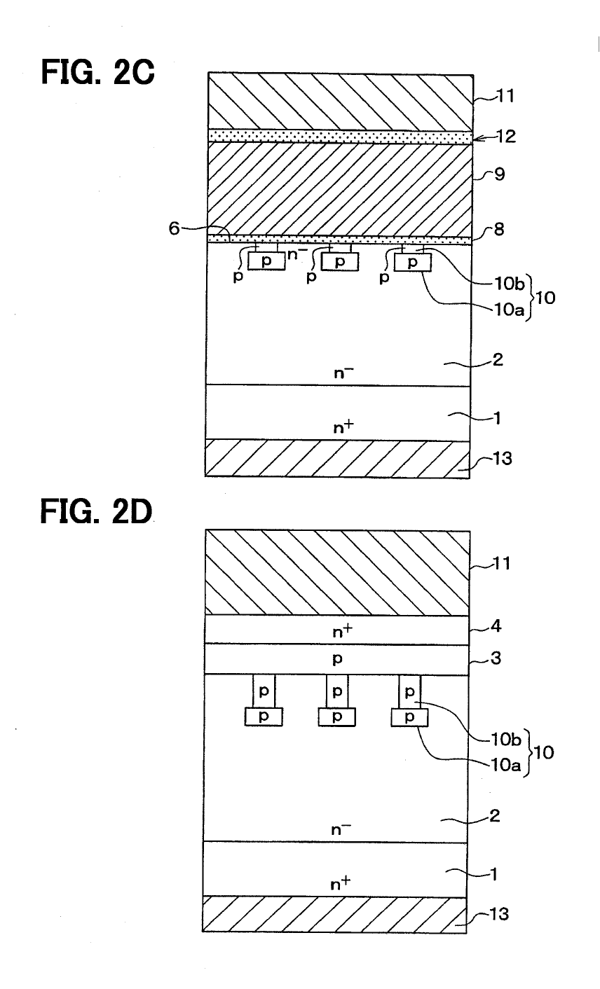

FIG. 1 is a perspective cross-sectional view of a MOSFET having a trench gate structure according to the present embodiment. This drawing corresponds to one cell of the MOSFET. Although only one cell of the MOSFET is shown in this diagram, two or more columns of MOSFETs having a similar structure to that of the MOSFET of FIG. 1 are arranged adjacent to each other. FIGS. 2A to 2D are cross-sectional views of the MOSFET of FIG. 1. FIG. 2A is a cross-sectional view taken along the line IIA-IIA in parallel with the xz plane in FIG. 1; FIG. 2B is a cross-sectional view taken along the line IIB-IIB in parallel with the xz plane in FIG. 1, FIG. 2C is a cross-sectional view of FIG. 1 taken along the line IIC-IIC in parallel with the yz plane in FIG. 1, and FIG. 2D is a cross-sectional view taken along the line IID-IID in parallel with the yz plane in FIG. 1.

In the MOSFET shown in FIG. 1 and FIGS. 2A to 2D, an n⁺ type substrate 1 made of SiC is used as a semiconductor substrate. The n⁺ type substrate 1 has, for example, a concentration of n type impurities, such as phosphorus, of 1.0×10¹⁹/cm³ and a thickness of about 300 micrometer. This n⁺ type substrate 1 has, on the surface thereof, an n⁻ type drift layer 2 having, for example, a concentration of n type impurities, such as phosphorus, of from 3.0×10¹⁵/cm³ to 7.0×10¹⁵/cm³ and a thickness of from about 10 to 15 micrometer and made of SiC. The impurity concentration of this n⁻ type drift layer 2 may be uniform in the depth direction, but preferably has a gradient concentration distribution in which the concentration of a portion of the n⁻ type drift layer 2 on the side of the n⁺ type substrate 1 is higher than that of a portion of the n⁻ type drift layer 2 on the side distant from the n⁺ type substrate 1. For example, it is recommended to make the impurity concentration of a portion of the n⁻ type drift layer 2 within a range from the surface of the n⁺ type substrate 1 to about 3 to 5 micrometer therefrom higher by about 2.0×10¹⁵/cm³ than another portion. This makes it possible to reduce the internal resistance of the n⁻ type drift layer 2, thereby achieving a reduction in on-resistance.

This n⁻ type drift layer 2 has, in the surface layer portion thereof, a p type base region 3 and the p type base region 3 has thereover an n⁺ type source region 4 and a p⁺ type contact layer 5.

The p type base region 3 has, for example, a concentration of p type impurities, such as boron or aluminum, of 5.0×10¹⁶ to 2.0×10¹⁹/cm³ and a thickness of about 2.0 micrometer. The n⁺ type source region 4 has, in the surface layer thereof, for example, a concentration of n type impurities (surface concentration) such as phosphorus of 1.0×10²¹/cm³ and a thickness of about 0.3 micrometer. The p⁺ type contact layer 5 has, in the surface layer thereof, for example, a concentration of p type impurities (surface concentration) such as boron or aluminum of 1.0×10²¹/cm³ and a thickness of about 0.3 micrometer. The n⁺ type source region 4 is placed on both sides of a trench gate structure which will be described later and the p⁺ type contact layer 5 is provided on the side opposite to the trench gate structure with the n⁺ type source region 4 therebetween.

A trench having, for example, a width of from 1.4 to 2.0 micrometer and a depth of 2.0 micrometer or greater (for example, 2.4 micrometer) is formed so as to penetrate through the p type base region 3 and the n⁺ type source region 4 and reach the n⁻ type drift layer 2. The p type base region 3 and the n⁺ type source region 4 are placed so as to be in contact with the side surface of this trench 6.

The inner wall surface of the trench 6 is covered with a gate oxide film 8 and the trench 6 is filled with a gate electrode 9 comprised of doped Poly-Si formed on the surface of the gate oxide film 8. The gate oxide film 8 is formed by thermally oxidizing the inner wall surface of the trench 6. The gate oxide film 8 has a thickness of about 100 nm both on the side surface and the bottom of the trench 6.

The trench gate structure has such a constitution. This trench gate structure extends with the y direction in FIG. 1 as a longitudinal direction. Two or more trench gate structures are arranged in parallel along the x direction of FIG. 1, thus forming a stripe pattern. The n⁺ type source region 4 and the p⁺ type contact layer 5 also extend along the longitudinal direction of the trench gate structure.

Further, p type deep layers 10 extending in a direction crossing the trench gate structure are formed in the n⁻ type drift layer 2 below the p type base region 3. In the present embodiment, the p type deep layers 10 extend in a normal direction (x direction in FIG. 1) relative to a portion of the side surface of the trench 6 in which a channel region is formed in the trench gate structure, that is, extend in a direction perpendicular to the longitudinal direction of the trench 6. A plurality of such p type deep layers 10 is arranged in the longitudinal direction of the trench 6. These p type deep layers 10 are formed deeper than the bottom of the trench 6. Their depth from the surface of the n⁻ type drift layer 2 is, for example, from about 2.6 to 3.0 micrometer (depth from the bottom portion of the p type base region 3 is, for example, from 0.6 to 1.0 micrometer). The p type deep layers 10 are in contact with the p type base region 3 so that they are fixed to a potential equal to that of the p type base region 3.

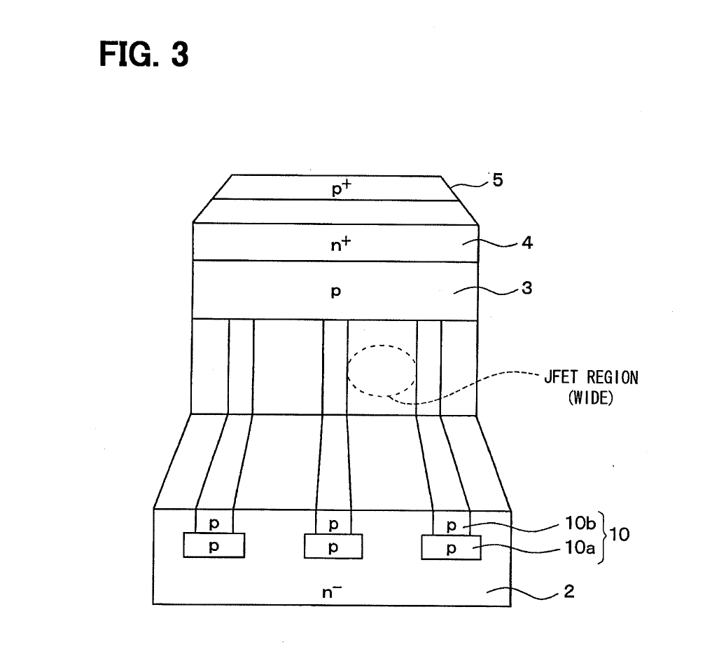

FIG. 3 is a partial perspective cross-sectional view of the vicinity of the trench 6 shown while omitting therefrom the gate oxide film 8, the gate electrode 9, and the like in the trench gate structure. As illustrated in FIG. 1, FIGS. 2A to 2D, and FIG. 3, the p type deep layers 10 of the present embodiment are each equipped with a lower layer region 10a corresponding to the first region and an upper layer region 10b corresponding to the second region, which regions have widths varied in stepwise manner. This means that in the present embodiment, the width of each of the p type deep layers 10 differs in width in the depth direction and the width in the upper portion is smaller than that in the lower portion. More specifically, in order to mitigate the electric field concentration in the gate oxide film 8 and thereby prevent dielectric breakdown, the width of the lower layer region 10a is set greater in expectation of breakdown voltage, while in order to increase the width of a JFET region and thereby reduce a JFET resistance, the width of the upper layer region 10b is set smaller than in the lower layer region 10a. With regard to the impurity concentration of each of the p type deep layers 10 comprised of the lower layer region 10a and the upper layer region 10b, the concentration of p type impurities such as boron or aluminum is set at, for example, from 1.0×10¹⁷/cm³ to 1.0×10¹⁹/cm³ in expectation of breakdown voltage so as to mitigate the electric field concentration in the gate oxide film 8 and prevent dielectric breakdown.

In the present embodiment, the depth of a boundary between the lower layer region 10a and the upper layer region 10b, in other words, the depth of the bottom surface of the upper layer region 10b is deeper than the trench 6 and the upper layer region 10b extends from the side surface to the bottom portion of the trench 6. In the present embodiment, when a gate voltage is applied to the gate electrode 9 and a channel is formed on the side surface of the trench 6, the width of the channel becomes a portion of the n⁻ drift layer 2 between narrow-width upper layer regions 10b up to the deepest portion of the trench 6 so that it becomes wider than the portion located between the lower layer regions 10a. Due to the upper layer region 10b having a width smaller than that of the lower layer region 10a, the width of a JFET region can be made wider compared with the case where all the widths of each of the p type deep layers 10 are made equal to that of the lower layer region 10a, making it possible to reduce a JFET resistance.

The n+ type source region 4, the p⁺ type contact layer 5, and the gate electrode 9 have on the surfaces thereof a source electrode 11 and gate wiring (not illustrated). The source electrode 11 and the gate wiring are each comprised of a plurality of metals (for example, Ni/AI). At least a portion of them to be brought into contact with an n type SiC (more specifically, the n⁺ type source region 4 and, when doped with n, the gate electrode 9) is comprised of a metal which can form an ohmic contact with the n type SiC and at least a portion of them to be brought into contact with a p type SiC (more specifically, p⁺ type contact layer 5 and, when doped with p, the gate electrode 9) is comprised of a metal which can form an ohmic contact with the p type SiC. The source electrode 11 and the gate wiring are formed on an interlayer insulating film 12 and therefore they are electrically insulated. Through a contact hole formed in the interlayer insulating film 12, the source electrode 11 is brought into electric contact with the n⁺ type source region 4 and the p⁺ type contact layer 5 and the gate wiring is brought into electric contact with the gate electrode 9.

The n⁺ type substrate 1 has, on the back surface side thereof, a drain electrode 13 electrically coupled to the n⁺ type substrate 1. Such a structure constitutes an n channel and inversion type MOSFET having a trench gate structure.

Such an inversion type MOSFET having a trench gate structure operates as follows. Before a gate voltage is applied to the gate electrode 9, no inversion layer is formed in the p type base region 3. Accordingly, even if a positive voltage is applied to the drain electrode 13, electrons cannot reach the p type base region 3 from the n⁺ type source region 4 and no electric current flows between the source electrode 11 and the drain electrode 13.

In an off state (gate voltage=0 V, drain voltage=650 V, source voltage=0 V), even when a voltage is applied to the drain electrode 13, it becomes a reverse bias so that a depletion layer expands from between the p type base region 3 and the n⁻ type drift layer 2. Since the impurity concentration of the p type base region 3 is higher than that of the n⁻ type drift layer 2, the depletion layer expands mostly toward the n⁻ type drift layer 2. For example, in the case where the impurity concentration of the p type base region 3 is 10 times higher than the impurity concentration of the n⁻ type drift layer 2, the depletion layer expands about 0.7 micrometer toward the p type base region 3 and about 7.0 micrometer toward the n⁻ type drift layer 2. However, the thickness of the p type base region 3 is set to 2.0 micrometer that is thicker than the expanding amount of the depletion layer so that occurrence of punching through can be prevented. Then, because the depletion layer expands more than the case where the drain is 0 V and a region that acts as an insulator further expands, electric current does not flow between the source electrode 11 and the drain electrode 13.

In addition, because the gate voltage is 0 V, an electric field is applied between the drain and the gate. Therefore, an electric field concentration may occur at the bottom of the gate oxide film 8. Since the p type deep layers 10 deeper than the trench 6 are provided, however, the depletion layer at a PN junction between the p type deep layers 10 and the n⁻ type drift layer 2 largely expands toward the n⁻ type drift layer 2 and a high voltage due to the influence of the drain voltage does not easily go into the gate oxide film 8. In particular, the width of the lower layer region 10a of the p type deep layers 10 is preset in expectation of a breakdown voltage so that it is possible to prevent a higher voltage from going into the gate oxide film 8. As a result, an electric field concentration in the gate oxide film 8, especially, an electric field concentration in the gate oxide film 8 at the bottom of the trench 6 can be mitigated, whereby breakage of the gate oxide film 8 can be prevented.

On the other hand, in an on state (gate voltage=20V, drain voltage=1V, and source voltage=0V), a gate voltage of 20V is applied to the gate electrode 9 so that a channel is formed on the surface of the p type base region 3 which is in contact with the trench 6. Electrons injected from the source electrode 11 reach the n⁻ type drift layer 2 after passing through the n⁺ type source region 4 and the channel formed on the p type base region 3. Accordingly, electric current can be provided between the source electrode 11 and the drain electrode 13.

Furthermore, in the present embodiment, the width of the upper layer region 10b of the p type deep layers 10 is made narrower than that of the lower layer region 10a and the width decreases in stepwise manner with a decrease in the depth of the p type deep layers 10. When a gate voltage is applied to the gate electrode 9 in an on state and a channel is formed, the channel can have a greater width. This means that near the upper portion of the p type deep layers 10, the width of a channel corresponds to a portion of the n⁻ type drift layer 2 located between two small-width upper layer regions 10b so that it becomes wider than a portion of the n⁻ type drift layer 2 located between wide-width lower layer portions 10a. As a result, the channel gets wider width. Compared with the case where all the widths of each of the p type deep layers 10 is made equal to the width of the lower layer region 10a, the width of the JFET region can be made wider, making it possible to reduce the JFET resistance.

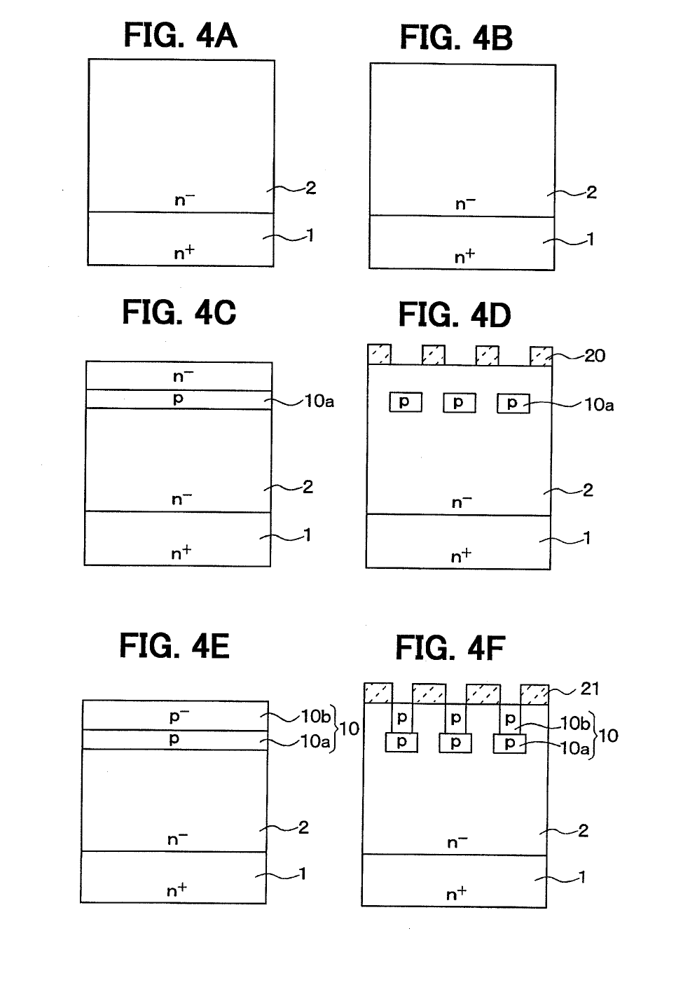

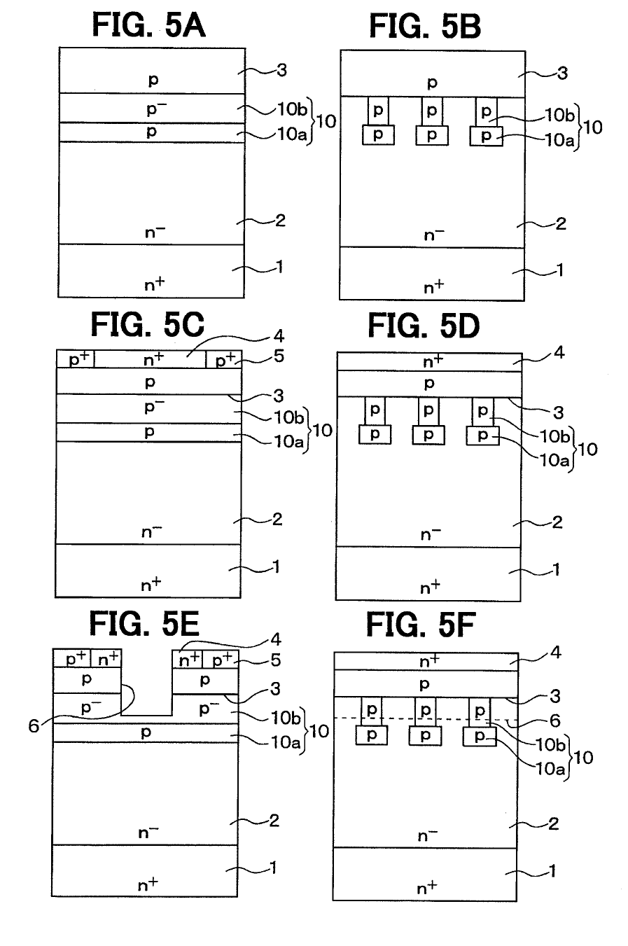

Next, a manufacturing method of the MOSFET having a trench gate structure as shown in FIG. 1 will be described. FIGS. 4A to 4F and 5A to 5F are cross-sectional views showing manufacturing steps of the MOSFET having a trench gate structure as shown in FIG. 1. In each of FIGS. 4A to 4F and 5A to 5F, a cross-sectional view (area corresponding to FIG. 2B) taken along the line IIB-IIB in parallel with the xz plane in FIG. 1 is shown on the left side, while a cross-sectional view (area corresponding to FIG. 2D) taken along the line IID-IID in parallel with the yz plane in FIG. 1 is shown on the right side. The description will next be made referring to these drawings.

(Step Shown in FIG. 4a and 4b)

First, an n⁺ type substrate 1 having, for example, a concentration of n type impurities, such as phosphorous, of 1.0×10¹⁹/cm³ and a thickness of about 300 micrometer is prepared. On the surface of the n⁺ type substrate 1, an n⁻ type drift layer 2 having, for example, a concentration of n type impurities, such as phosphorus, of from 3.0×10¹⁵/cm³ to 7.0×10¹³/cm³ and a thickness of about 15 micrometer and made of SiC is formed by epitaxial growth.

(Step Shown in FIGS. 4C and 4D)

After formation of a mask 20 made of LTO or the like on the surface of the n⁻ type drift layer 2, the mask 20 is opened at a predetermined formation region of a lower layer region 10a of p type deep layers 10 through photolithography. Then, p type impurities (such as boron or aluminum) are implanted from above the mask 20. Ion implantation is performed to give a boron or aluminum concentration of, for example, from 1.0×10¹⁷/cm³ to 1.0×10¹⁹/cm³. Then, the mask 20 is removed.

(Step Shown in FIGS. 4E and 4F)

After formation of a mask 21 made of LTO or the like on the surface of the n⁻ type drift layer 2, the mask 21 is opened at a predetermined formation region of an upper layer region 10b of the p type deep layers 10 through photolithography. Then, p type impurities (such as boron or aluminum) are implanted from above the mask 21. The concentration upon ion implantation is set similar to that in the step shown in FIGS. 4C and 4D. After removal of the mask 21, the ions thus implanted are activated.

In the above description, ion implantation of p type impurities for the formation of the lower layer region 10a is followed by ion implantation of p type impurities for the formation of the upper layer region 10b, but they may be performed in reverse order. When ion implantation of p type impurities for the formation of the upper layer region 10b is performed first, it is also possible to use the mask 21 in common to form the lower layer region 10a. For example, after formation of the upper layer region 10b, the opening end of the opening portion formed in the mask 21 is caused to retreat by etching with hydrofluoric acid or the like and the width of the opening portion is changed to a width corresponding to the lower layer region 10a. With the mask 21 changed in the width of the opening portion, p type impurities are implanted in order to form the lower layer region 10a. This permits using a mask in common. In addition, by causing the opening end of the mask 21 to retreat by etching and thereby forming an opening portion corresponding to the lower layer region 10a, the upper layer region 10a and the lower layer region 10b can be formed in self alignment, making it possible to avoid an influence of misalignment.

(Step Shown in FIGS. 5A and 5B)

A p type base region 3 is formed by the epitaxial growth of a p type impurity layer having, for example, a concentration of p type impurities, such as boron or aluminum, of from 5.0×10¹⁵ to 5.0×10¹⁶/cm³ and a thickness of about 2.0 micrometer on the surface of the n⁻ type drift layer 2.

(Step Shown in FIGS. 5C and 5D)

Then, after formation of a mask (not illustrated) made of, for example, LTO on the p type base region 3, photolithography is conducted to form an opening in the mask at a predetermined formation region of an n⁺ type source region 4. After that, n type impurities (such as nitrogen) are implanted.

Then, after removal of the mask used previously, another mask (not illustrated) is formed. Photolithography is performed to form an opening in the mask at a predetermined formation region of a p⁺ type contact layer 5. Then, p type impurities (such as boron or aluminum) are implanted.

The ions thus implanted are then activated to form both an n⁺ type source region 4 having, for example, a concentration (surface concentration) of n type impurities such as phosphorus of 1.0×10²¹/cm³ and a thickness of about 0.3 micrometer and a p⁺ type contact layer 5 having, for example, a concentration (surface concentration) of p type impurities such as boron or aluminum of about 1.0×10²¹/cm³ and a thickness of about 0.3 micrometer. After that, the mask is removed.

(Step Shown in FIGS. 5E and 5F)

After formation of an etching mask, which is not illustrated, on the p type base region 3, the n⁺ type source region 4, and the p⁺ type contact layer 5, the etching mask is opened at a predetermined formation region of a trench 6. Then, anisotropic etching is performed with the etching mask, followed by isotropic etching or sacrificial oxidation if needed to form the trench 6. After this, the etching mask is removed.

Steps thereafter are similar to the conventional steps so that they are not illustrated. First, a gate oxide film formation step is performed to form a gate oxide film 8 on the entire surface of the substrate including the inside of the trench 6. More specifically, the gate oxide film 8 is formed by gate oxidation (thermal oxidation) by a pyrogenic method using a wet atmosphere. Next, an about 440-nm thick polysilicon layer doped with n type impurities is formed on the surface of the gate oxide film 8 at a temperature of, for example, 600 degrees C. and then, an etch back step or the like is performed to make the poly silicon layer thinner. After formation of an interlayer insulating film 12, the interlayer insulating film 12 is patterned to form contact holes to be connected to the n⁺ type source region 4 or the p⁺ type contact layer 5 and at the same time, to form contact holes to be connected to the gate electrode 9 on another cross section. Next, after a film of an electrode material is formed to fill the contact holes therewith, it is patterned to form a source electrode 11 and a gate wiring. A drain electrode 13 is formed on the back surface side of the n⁺ type substrate 1. As a result, the MOSFET shown in FIG. 1 is completed.

As described above, the SiC semiconductor device of the present embodiment has a structure in which the width of the p type deep layers 10 is made smaller in stepwise manner with a decrease in the depth thereof. Described specifically, the p type deep layers 10 are each comprised of a lower layer region 10a and an upper layer region 10b and the width of the upper layer region 10b is made smaller than that of the lower layer region 10a. When a gate voltage is applied to the gate electrode 9 in an on state and a channel is formed, this structure leads to an increase in the width of the channel near the upper portion of the p type deep layers 10, an increase in the width of a JFET region compared with the case where the width of each of the p type deep layers 10 is made uniform in any portion, that is, the whole width is made equal to the width of the lower layer region 10a, and a reduction in JFET resistance. When the p type deep layers 10 are formed so as to cross the trench 6 constituting the trench gate structure, the JFET resistance in the JFET region formed between two p type deep layers 10 adjacent to each other can be reduced, making it possible to reduce the on resistance.

### Second Embodiment

A second embodiment will next be described. The SiC semiconductor device of this embodiment is different from that of the first embodiment in the structure of the p type deep layers 10. Since they are similar in the fundamental structure, only portions different from the first embodiment will next be described.

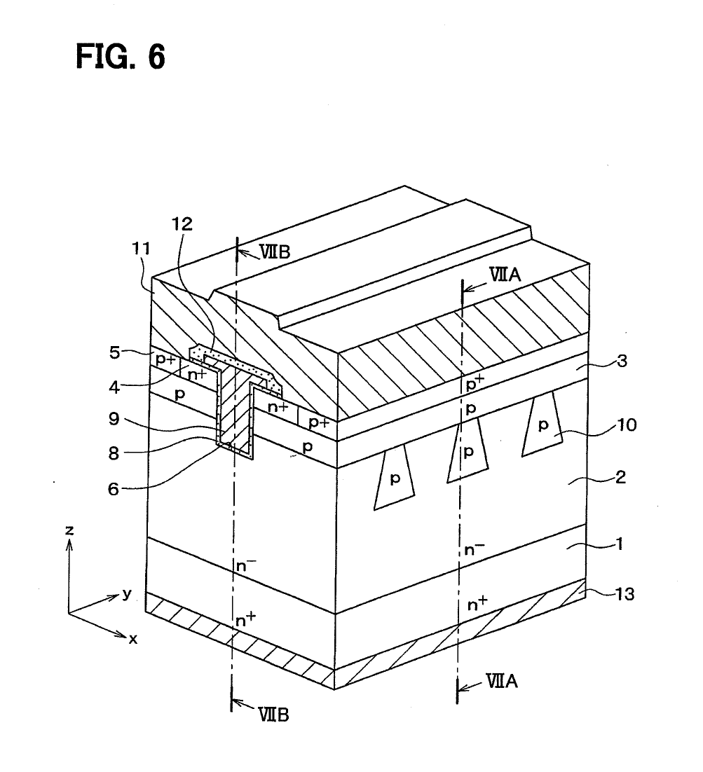

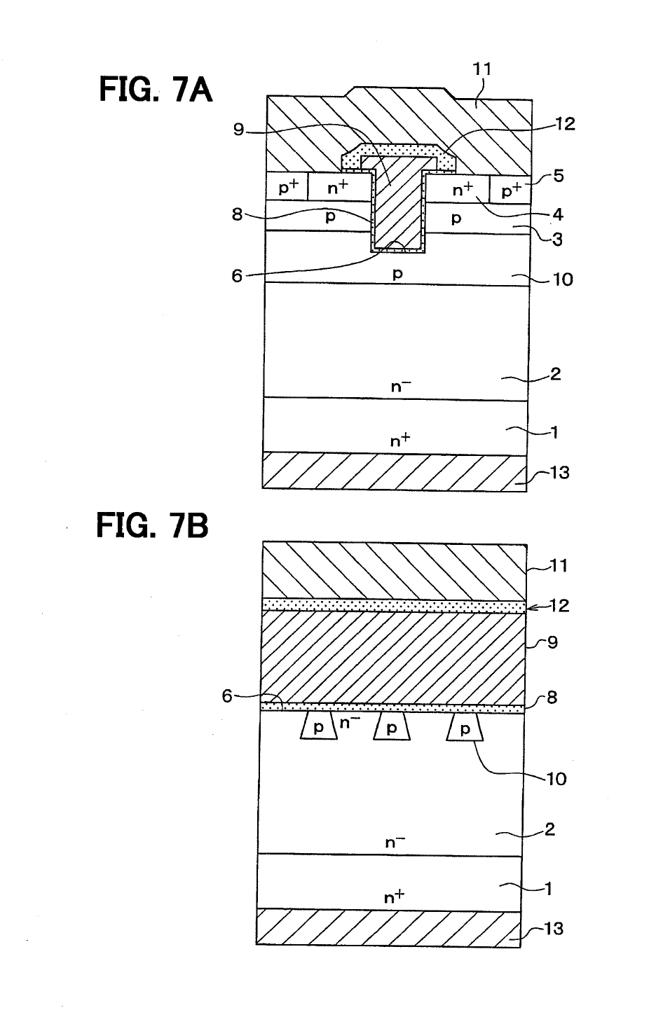

FIG. 6 is a perspective cross-sectional view of the SiC semiconductor device according to this embodiment. FIG. 7A is a cross-sectional view taken along the line VIIA-VIIA in parallel with the xz plane in FIG. 6 and FIG. 7B is a cross-sectional view taken along the line VIIB-VIIB in parallel with the yz plane in FIG. 6.

As illustrated in FIG. 6 and FIGS. 7A and 7B, also in this embodiment, similar to the first embodiment, the width of each of the p type deep layers 10 is changed in the depth direction of the p type deep layers 10 and the width of the upper portion of the p type deep layers 10 is made smaller than that of the lower portion. More specifically, the width of the bottom portion of the p type deep layers 10 is set in consideration of a breakdown voltage and from the bottom portion thereof, the width is decreased gradually with a decrease in the depth of the p type deep layers 10. Even in such a structure, as in the first embodiment, the width of the bottom portion of the p type deep layers 10 is made wider to ensure a breakdown voltage and at the same time, a wide channel can be formed by decreasing the width of the upper portion of the p type deep layers 10. This enables widening of a current path. As a result, a JFET resistance in a JFET region formed between two adjacent p type deep layers 10 can be reduced further and a further reduction in on resistance can be achieved.

The manufacturing method of a SiC semiconductor device having the structure of the present embodiment is basically similar to that of the first embodiment. It is only necessary to diagonally implant p type impurities with the mask 21 when the p type deep layers 10 as shown in FIGS. 4C and 4D are formed, and thereby form the p type deep layers 10 in the diagonal direction.

### Third Embodiment

A third embodiment will next be described. The SiC semiconductor device of this embodiment has a structure capable of reducing the on resistance further compared with that of the first embodiment. Since they are similar in the fundamental structure, only portions different from the first embodiment will next be described.

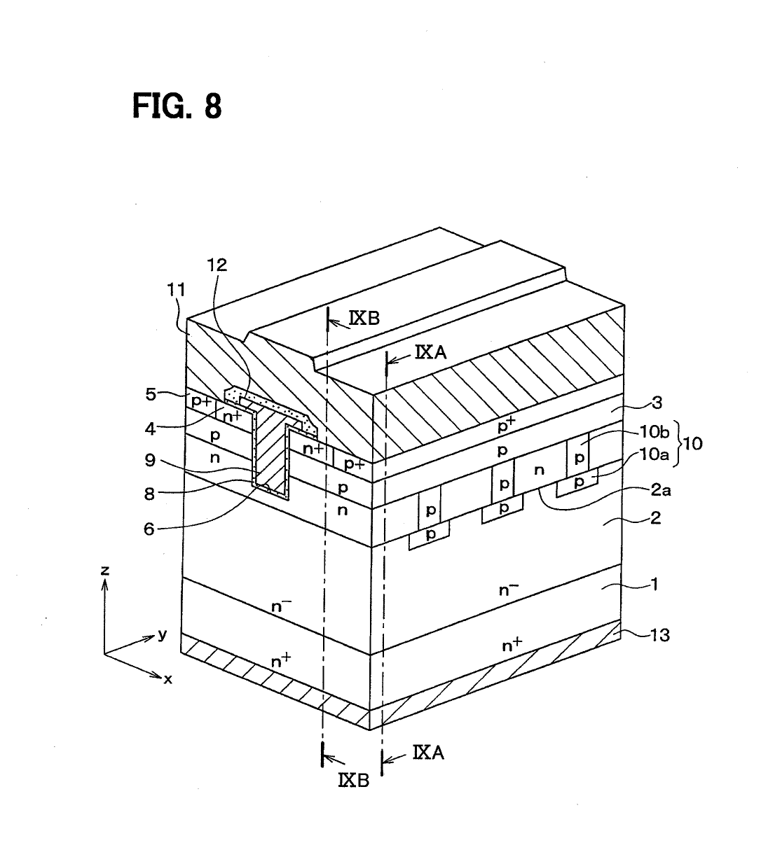

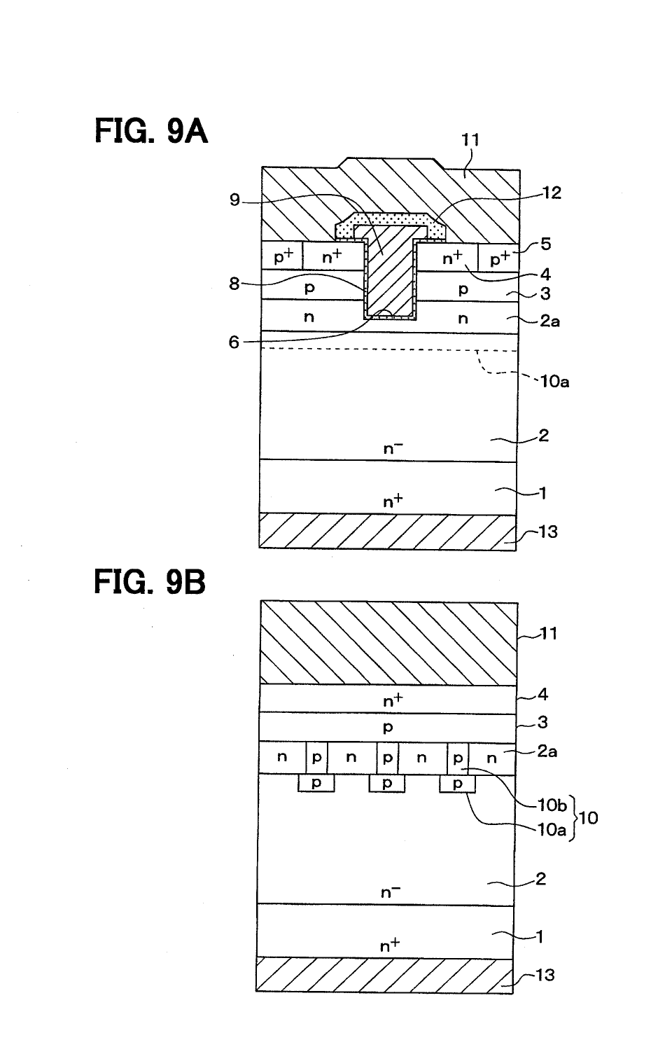

FIG. 8 is a perspective cross-sectional view of the SiC semiconductor device according to the present embodiment. FIG. 9A is a cross-sectional view taken along the line IXA-IXA in parallel with the xz plane in FIG. 8 and FIG. 9B is a cross-sectional view taken along the line IXB-IXB in parallel with the yz plane in FIG. 8.

In this embodiment, as shown in FIG. 8 and FIGS. 9A and 9B, a current diffusion layer 2a is formed by setting high the n type impurity concentration on the surface side of the n⁻ type drift layer 2, that is, on the side opposite to the n⁺ type substrate 1. The current diffusion layer 2a is provided in order to widen a current flowing region in an on state and the current diffusion layer 2a has an impurity concentration of, for example, from 5.0×10¹⁶ to 1.5×10¹⁷/cm³. The current diffusion layer 2a has, for example, a thickness of from 0.3 to 0.7 micrometer. In the present embodiment, it is equal to the depth of the upper layer region 10b of the p type deep layers 10.

In the SiC semiconductor device having such a structure, when a gate voltage is applied to the gate electrode 9 in an on state, a channel is formed on the surface of the p type base region 3 contiguous to the trench 6 and electrons injected from the source electrode 11 reach the current diffusion layer 2a of the n⁻ type drift layer 2 after passing through the n⁺ type source region 4 and the channel formed on the p type base region 3. As a result, a current flowing region becomes wider in the low-resistance current diffusion layer 2a and electric current reaches even a position distant from the trench gate structure, which contributes to a further reduction in on-resistance.

Thus, the p type deep layers 10 each comprised of the lower layer region 10a and the upper layer region 10b may be equipped with the current diffusion layer 2a. This enables to achieve a further reduction in on-resistance.

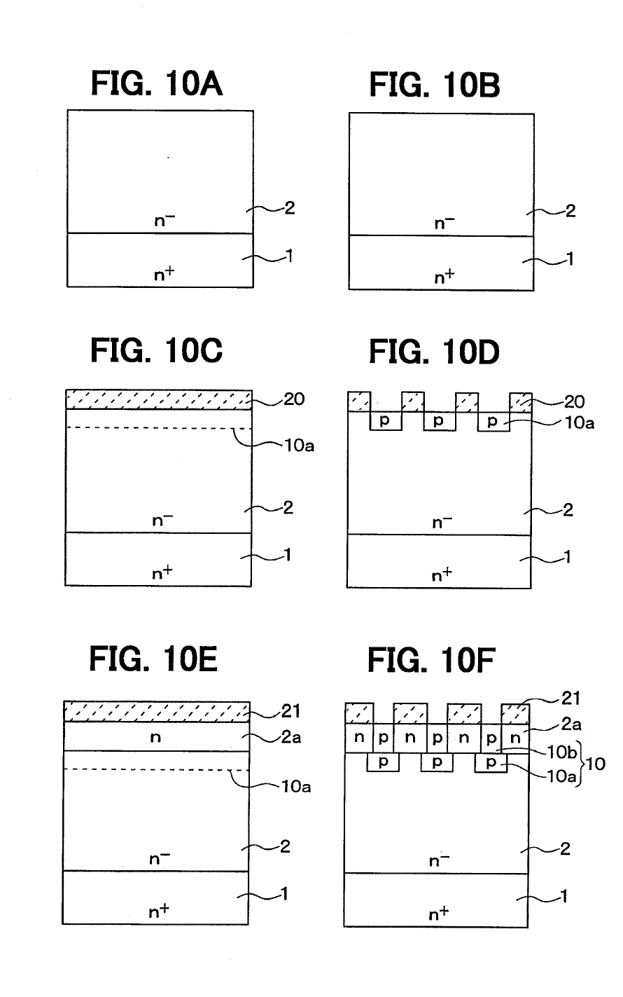

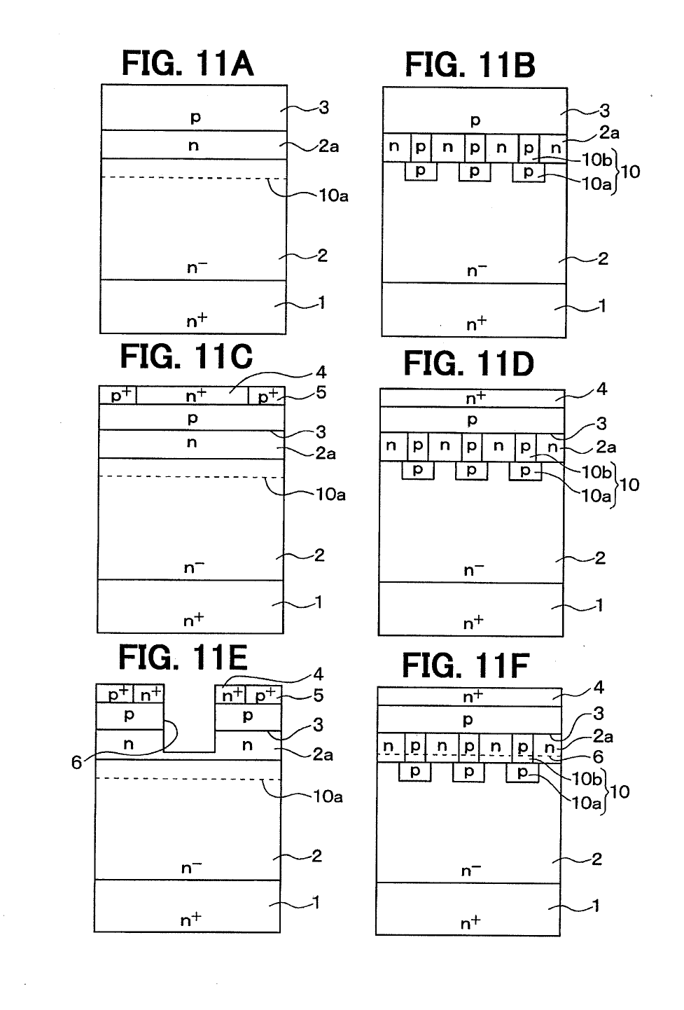

A manufacturing method of the SiC semiconductor device having the structure of the present embodiment will next be described. FIGS. 10A to 10F and FIGS. 11A to 11F are cross-sectional views showing manufacturing steps of such a SiC semiconductor device of the present embodiment. In FIGS. 10A to 10F and 11A to 11F, a cross-sectional view (area corresponding to FIG. 9A) taken along the line IXA-IXA in parallel with the xz plane in FIG. 8 is shown on the left side and a cross-sectional view (area corresponding to FIG. 9B) taken along the line IXB-IXB in parallel with the yz plane in FIG. 8 is shown on the right side. The manufacturing method of the SiC semiconductor device of the present embodiment will next be described referring to these drawings.

First, in the step shown in FIGS. 10A and 10B, an n⁻ type drift layer 2 is formed by epitaxial growth on the surface of the n⁺ type semiconductor substrate 1. At this time, a portion of the n⁻ type drift layer 2 other than the current diffusion layer 2a is formed (first step). Then, in the step shown in FIGS. 10C and 10D, after a mask 20 is placed on the surface of the n⁻ type drift layer 2, the mask 20 is opened at a predetermined formation region of an upper layer region 10b of p type deep layers 10. P type impurities (such as boron or aluminum) are implanted from above the mask 20.

After removal of the mask 20, in the step shown in FIGS. 10E and 10F, a current diffusion layer 2a having, for example, an n type impurity concentration of from 5.0×10¹⁶ to 1.5×10¹⁷/cm³ and a thickness of from 0.3 to 0.7 micrometer is formed (second step). After formation of a mask 21 on the surface of the current diffusion layer 2a, the mask 21 is opened at a predetermined formation region of an upper layer region 10b of the p type deep layers 10. From above the mask 21, p type impurities (such as boron or aluminum) are implanted. After removal of the mask 21, the ions thus implanted are activated. In such a manner, the upper layer region 10 b is formed by partial p-type compensation of the current diffusion layer 2a and is then connected to the lower layer region 10a formed in advance to constitute the p type deep layers 10.

Then, in the steps shown in FIGS. 11A to 11F, steps similar to those employed in those shown in FIGS. 5A to 5F are performed to complete the SiC semiconductor device of the present embodiment shown in FIG. 8.

### Fourth Embodiment

A fourth embodiment will next be described. The SiC semiconductor device of the present embodiment has a structure more effective than that of the third embodiment in mitigating a field effect concentration in the gate oxide film 8. It is basically similar to the third embodiment so that only a portion different from the third embodiment will next be described.

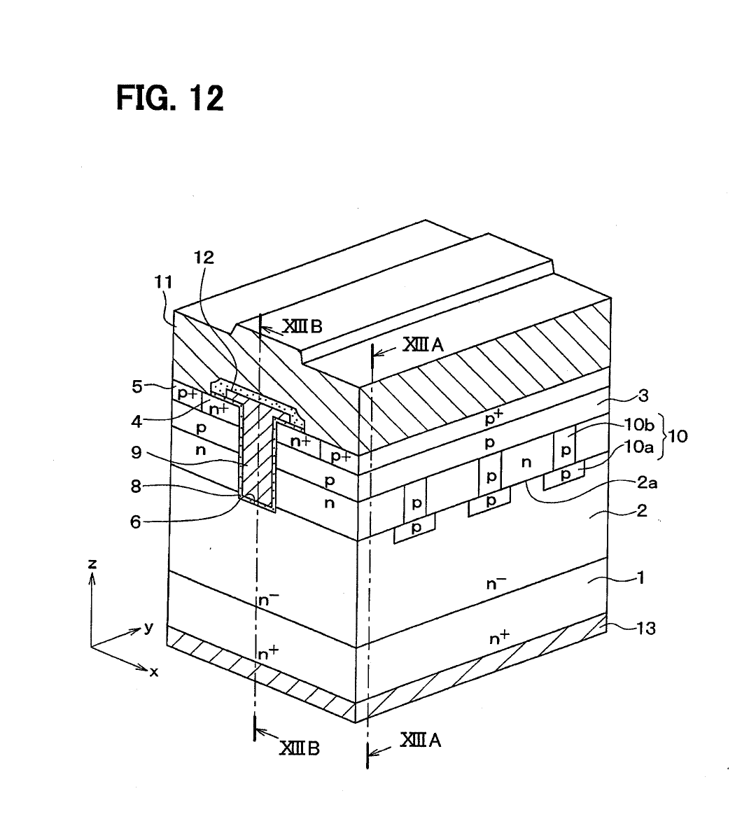

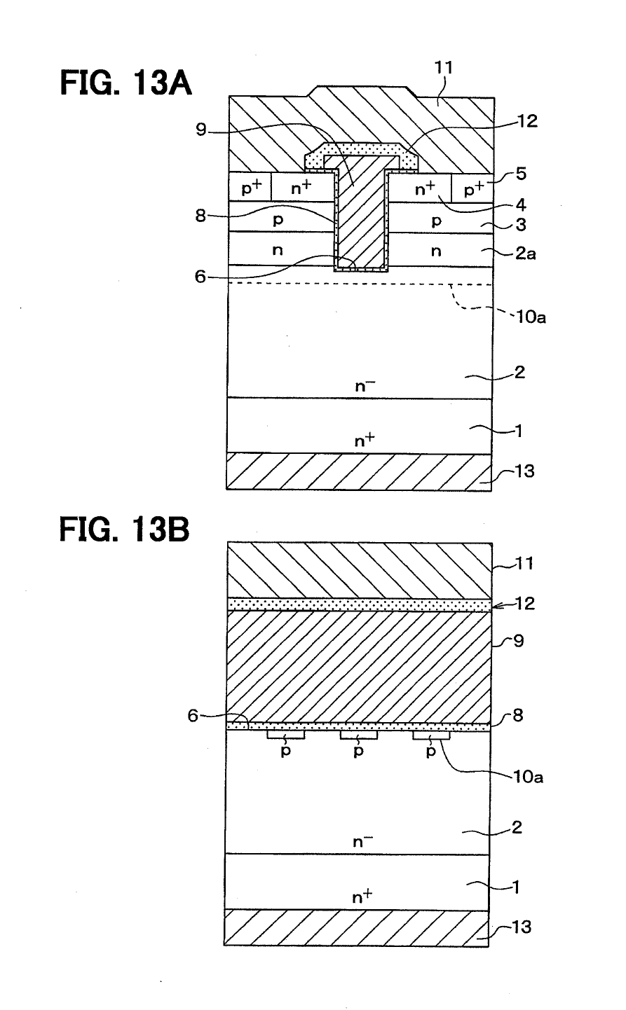

FIG. 12 is a perspective cross-sectional view of the SiC semiconductor device according to the present embodiment. FIG. 13A is a cross-sectional view taken along the line XIIIA-XIIIA in parallel with the xz plane in FIG. 12 and FIG. 13B is a cross-sectional view taken along the line XIIIB-XIIIB in parallel with the yz plane in FIG. 12.

In the present embodiment, as shown in FIG. 12 and FIGS. 13A and 13B, the current diffusion layer 2a is formed on the surface side of the n⁻ type drift layer 2 as in the third embodiment and at the same time, the trench 6 penetrates through the current diffusion layer 2a and the bottom of the trench 6 is formed at a position deeper than the current diffusion layer 2a.

In the SiC semiconductor device having such a structure, since the trench gate structure is formed at a position deeper than the current diffusion layer 2a, the electric field concentration to the gate oxide film 8 can be mitigated more than that in the third embodiment. More specifically, the current diffusion layer 2a is a portion of the n⁻ type drift layer 2 having a relatively high impurity concentration and an electric field concentration tends to occur at a site where the impurity concentration is high. The electric field concentration can be mitigated by extending the depth of the trench gate structure to a position deeper than the current diffusion layer 2a, that is, a position having a relatively low impurity concentration in the n⁻ type drift layer 2. As a result, it becomes possible to prevent the gate oxide film 8 from being broken by the electric field concentration.

The manufacturing method of the SiC semiconductor device having such a structure is almost similar to that of the third embodiment. It is only necessary to change the formation depth of the trench 6 in the step of FIGS. 1E and 11F described in the third embodiment and extend the depth of the trench 6 to exceed the current diffusion layer 2a. Needless to say, it is also possible not to change the formation depth of the trench 6 but to decrease the thickness of the current diffusion layer 2a compared with that of the third embodiment, thereby extending the bottom of the trench 6 to a position deeper than the current diffusion layer 2a.

### Fifth Embodiment

A fifth embodiment will next be described. The SiC semiconductor device of the present embodiment is different from that of the third embodiment in the concentration of the current diffusion layer 2a. It is similar to the third embodiment in basic structure so that only a portion different from that of the third embodiment will next be described.

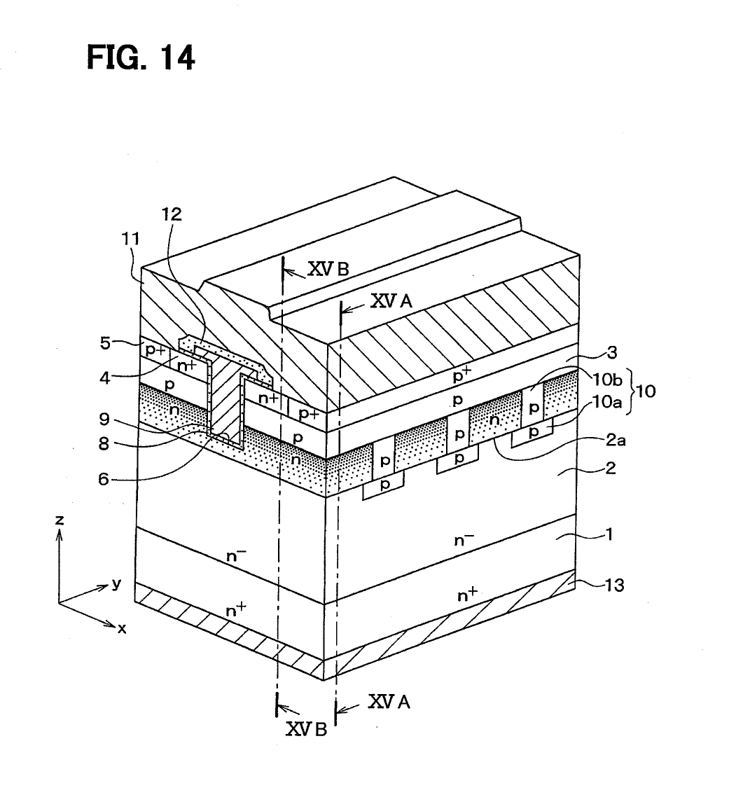

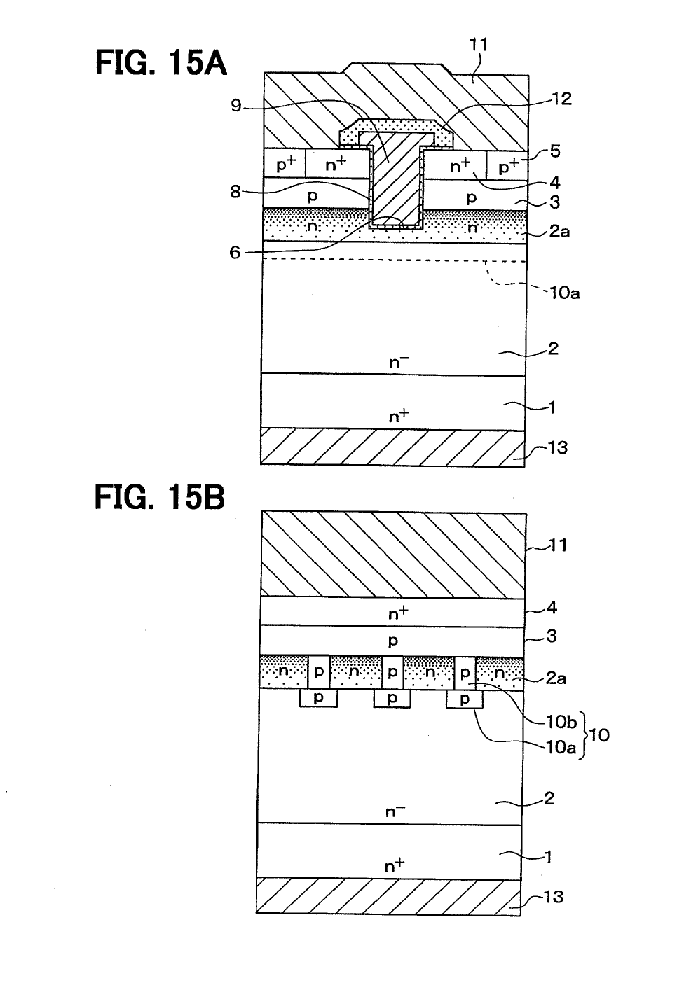

FIG. 14 is a perspective cross-sectional view of the SiC semiconductor device of the present embodiment. FIG. 15A is a cross-sectional view taken along the line XVA-XVA in parallel with the xz plane in FIG. 14 and FIG. 15B is a cross-sectional view taken along the line XVB-XVB in parallel with the yz plane in FIG. 14, respectively.

As shown in FIG. 14 and FIGS. 15A and 15B, the current diffusion layer 2a is formed on the surface side of the n⁻ type drift layer 2 as in the third embodiment. A concentration distribution is provided in the current diffusion layer 2a so that the n type impurity concentration of the current diffusion layer 2a is lower in the lower portion and higher in the upper portion.

In the SiC semiconductor device having such a structure, the concentration of n type impurities in the lower portion of the current diffusion layer 2a is set lower so that the bottom portion of the trench 6 is located at a position having a relatively low impurity concentration. This enables to mitigate the electric field concentration to the gate oxide film 8. On the other hand, the n type impurity concentration is made higher in the upper portion of the current diffusion layer 2a so that a current flowing region can be widened further in the low-resistance current diffusion layer 2a and a reduction in on resistance can also can be achieved. Accordingly, both the prevention of breakage of the gate oxide film 8 due to a high electric field and the reduction in on resistance can be achieved.

A manufacturing method of the SiC semiconductor device having such a structure is almost similar to that of the third embodiment. It is only necessary to perform epitaxial growth for the formation of the current diffusion layer 2a in the step of FIGS. 10E and 10F described in the third embodiment while gradually increasing the doping amount of n type impurities.

Such a structure in which the current diffusion layer 2a has, in the depth direction thereof, a distribution in the n type impurity concentration can also be applied to the fourth embodiment described above.

### OTHER EMBODIMENTS

In each of the above embodiments, examples of the structure in which the p type deep layers 10 have a width narrower in the upper portion and a width wider than in the lower portion are described. In the first and third embodiments, the p type deep layers 10 have a width showing a stepwise decrease with a decrease in the depth of the p type deep layers and in the second embodiment, the p type deep layers 10 have a width showing a gradual decrease width with a decrease in the depth of the p type deep layers 10. They are merely examples and even another structure can also produce an on-resistance decreasing effect attributable to a reduction in the JFET resistance insofar as the p type deep layers 10 have a width narrower in the upper portion and wider in the lower portion. Needless to say, in the structure as described in the first or third embodiment in which the width of the p type deep layer 10 is changed in stepwise manner, the number of steps may be increased to more than two.

In each of the above-described embodiments, the p type deep layers 10 are extended in the x direction, but the p type deep layers 10 may be diagonally crossed with the longitudinal direction of the trench 6 or may be divided into two or more layers in the x direction. In the case where the p type deep layers 10 are diagonally crossed with the longitudinal direction of the trench 6, it is preferred, in order to prevent an uneven equipotential distribution, to arrange the p type deep layers 10 in line symmetry, with a line extending in a direction perpendicular to the longitudinal direction of the trench 6 as a symmetry line.

In each of the above embodiments, the description is made with, as an example, an n channel type MOSFET having an n type as the first conductivity type and a p type as the second conductivity type. The disclosure can also be applied to a p channel type MOSFET in which the conductivity type of each of the constituting elements have been reversed. In addition, in the above description, a MOSFET having a trench gate structure is used as an example. The disclosure can also be applied to an IGBT having a similar trench gate structure. The structure or the manufacturing method of the IGBT is similar to that of the above embodiments except that the conductivity type of the substrate 1 is changed from n type to p type.

In each of the above embodiments, the gate oxide film 8 made by thermal oxidation is used as an example of a gate insulating film. The gate insulating film is not limited thereto but it may include an oxide film not formed by thermal oxidation or a nitride film.

In the third embodiment, the manufacturing method of a SiC semiconductor device includes steps shown in FIGS. 10A to 10F and FIGS. 11A to 11F. Alternatively, it is also possible to basically perform steps similar to those employed in the first embodiment and, in the final stage of the formation step of the n⁻ type drift layer 2 shown in FIGS. 4A and 4B, to form the current diffusion layer 2a by increasing the concentration of impurities to be doped upon growth. Also in this case, by setting higher the concentration of p type impurities to be implanted upon formation of the upper layer region 10b shown in FIGS. 4E and 4F than that in the first embodiment, the SiC semiconductor device having the structure shown in FIG. 8 can be manufactured.

Furthermore, in the third embodiment, the current diffusion layer 2a is formed in the structure in which each of the p type deep layers 10 is comprised of the lower layer region 10a and the upper layer region 10b as in the first embodiment, but it is also possible to form the current diffusion layer 2a in the structure of the second embodiment.

The above disclosure has the following aspects.

According to a first aspect of the present disclosure, a silicon carbide semiconductor device includes: an inversion type semiconductor switching element. The inversion type semiconductor switching element includes: a substrate having a first or second conductivity type and made of silicon carbide; a drift layer disposed on the substrate, having an impurity concentration lower than the substrate, having the first conductivity type, and made of silicon carbide; a base region disposed on the drift layer, having the second conductivity type, and made of silicon carbide; a source region disposed in an upper portion of the base region, having an impurity concentration higher than the drift layer, having the first conductivity type, and made of silicon carbide; a contact region disposed in another upper portion of the base region, having an impurity concentration higher than the base layer, having the second conductivity type, and made of silicon carbide; a trench extending from a surface of the source region to penetrate the base region and having a first direction as a longitudinal direction; a gate insulating film disposed on an inner wall of the trench; a gate electrode disposed on the gate insulating film in the trench; a source electrode electrically coupled with the source region and the base region; and a drain electrode disposed on a back side of the substrate. The inversion type semiconductor switching element is configured to flow current between the source electrode and the drain electrode via the source region, an inversion type channel region and the drift layer. The inversion type channel region is provided in a portion of the base region positioned on a side of the trench by controlling a voltage applied to the gate electrode. The inversion type semiconductor switching element further includes: a plurality of deep layers having the second conductivity type. Each deep layer is disposed in an upper portion of the drift layer below the base region, has a depth deeper than the trench, and extends along a second direction, which crosses the first direction. Each deep layer has an upper portion and a lower portion. A width of the upper portion is narrower than the lower portion.

In the above device, since the width of the upper portion is narrower than the lower portion, a channel width around the upper portion of the deep layer is expanded when a gate voltage is applied to the gate electrode to form the channel around the upper portion of the deep layer. Thus, a width of a JFET region is wider than a case where a width of the deep layer is constant. In this case, a JFET resistance is reduced, and an on-state resistance is also reduced.

Alternatively, a width of each deep layer may decrease in a stepwise manner as a depth of the deep layer gets shallower.

Alternatively, a width of each deep layer may decrease gradually as a depth of the deep layer gets shallower.

Alternatively, the inversion type semiconductor switching element may further include a current diffusion layer having the first conductivity type. The current diffusion layer is disposed in the drift layer between the plurality of deep layers, and the current diffusion layer has an impurity concentration higher than the drift layer, which is located below the deeper layer. Since the current diffusion layer has a low resistance, an area in the current diffusion layer, in which the current flows, is expanded, so that the on-state resistance is much reduced.

Further, a bottom of the trench may be deeper than the current diffusion layer. In this case, the trench reaches the drift layer, which has a comparatively low impurity concentration, so that an electric field concentration is reduced. Thus, the device protects the gate insulation film from being damaged by the electric field concentration.

Alternatively, the current diffusion layer may have an impurity concentration distribution in a depth direction, and the impurity concentration of the current diffusion layer increases as a depth of the current diffusion layer gets shallower. In this case, since the lower portion of the current diffusion layer has a comparatively low impurity concentration, the bottom of the trench is disposed at the lower portion of the current diffusion layer having the low impurity concentration. Accordingly, the electric field concentration at the gate insulation film is reduced. On the other hand, since the upper portion of the current diffusion layer has a comparatively high impurity concentration, an area in the current diffusion layer having the low resistance, in which the current flows, is expanded. Thus, the on-state resistance is reduced. In this case, the damage of the gate insulation film is prevented, and the on-state resistance is reduced.

According to a second aspect of the present disclosure, a method for manufacturing a silicon carbide semiconductor device includes: forming a drift layer on a substrate, wherein the substrate is made of silicon carbide and has a first or second conductivity type, and the drift layer is made of silicon carbide, has the first conductivity type, and has an impurity concentration lower than the substrate; forming a plurality of deep layers having the second conductivity type in a surface portion of the drift layer by implanting ions on a surface of the drift layer through a first mask after the first mask is formed on the surface of the drift layer; forming a base region having the second conductivity type and made of silicon carbide on the deep layers and the drift layer; forming a source region in a surface portion of the base region by implanting a first conductivity type impurity on a surface of the base region, wherein the source region has an impurity concentration higher than the drift layer, having the first conductivity type, and made of silicon carbide; forming a contact region in another surface portion of the base region by implanting a second conductivity type impurity on the surface of the base region, wherein the contact region has an impurity concentration higher than the base region, having the second conductivity type, and made of silicon carbide; forming a trench on a surface of the source region to penetrate the base region and to reach the drift layer, wherein the trench is shallower than each deep layer, and has a first direction as a longitudinal direction; forming a gate insulating film on an inner wall of the trench; forming a gate electrode on the gate insulating film in the trench; forming a source electrode to be electrically coupled with the base region via the source region and the contact region; and forming a drain electrode on a back side of the substrate. Each deep layer is disposed in an upper portion of the drift layer below the base region, has a depth deeper than the trench, and extends along a second direction, which crosses the first direction. Each deep layer has an upper portion and a lower portion, and a width of the upper portion is narrower than the lower portion.

In the above method, since the width of the upper portion is narrower than the lower portion, a channel width around the upper portion of the deep layer is expanded when a gate voltage is applied to the gate electrode to form the channel around the upper portion of the deep layer. Thus, a width of a JFET region is wider than a case where a width of the deep layer is constant. In this case, a JFET resistance is reduced, and an on-state resistance is also reduced.

Alternatively, the forming of the deep layers may include: forming a second mask on the surface of the drift layer; partially opening the second mask; implanting a second conductivity type impurity on the surface of the drift layer through the second mask to form a first region of each deep layer; forming a third mask on the surface of the drift layer; partially opening the third mask; and implanting a second conductivity type impurity on the surface of the drift layer through the third mask to form a second region of each deep layer. The second region is located above the first region, and a width of the second region is narrower than the first region.

Alternatively, the forming of the deep layers may include: forming a third mask on the surface of the drift layer; partially opening the third mask; implanting a second conductivity type impurity on the surface of the drift layer through the third mask to form a second region of each deep layer; expanding an opening of the third mask so that a second mask having an opening corresponding to a first region of each deep layer is formed; and implanting a second conductivity type impurity on the surface of the drift layer through the second mask to form the first region of each deep layer. The second region is located above the first region, and a width of the second region is narrower than the first region.

Further, the method for manufacturing the silicon carbide semiconductor device may further include: forming a current diffusion layer having the first conductivity type in the drift layer between the plurality of deep layers. The current diffusion layer has an impurity concentration higher than the drift layer, which is located below the deeper layer. The implanting of the second conductivity type impurity to form the first region of each deep layer is performed after the forming of the drift layer and before the forming of the current diffusion layer so that the first region of each deep layer is embedded in the drift layer, and the implanting of the second conductivity type impurity to form the second region of each deep layer is performed after the forming of the current diffusion layer so that the second region of each deep layer is embedded in the current diffusion layer.

While the disclosure has been described with reference to embodiments thereof, it is to be understood that the disclosure is not limited to the embodiments and constructions. The disclosure is intended to cover various modification and equivalent arrangements. In addition, while the various combinations and configurations, which are preferred, other combinations and configurations, including more, less or only a single element, are also within the spirit and scope of the disclosure.

1. A silicon carbide semiconductor device comprising:
an inversion type semiconductor switching element,
wherein the inversion type semiconductor switching element includes:
a substrate having a first or second conductivity type and made of silicon carbide;
a drift layer disposed on the substrate, having an impurity concentration lower than the substrate, having the first conductivity type, and made of silicon carbide;
a base region disposed on the drift layer, having the second conductivity type, and made of silicon carbide;
a source region disposed in an upper portion of the base region, having an impurity concentration higher than the drift layer, having the first conductivity type, and made of silicon carbide;
a contact region disposed in another upper portion of the base region, having an impurity concentration higher than the base layer, having the second conductivity type, and made of silicon carbide;
a trench extending from a surface of the source region to penetrate the base region and having a first direction as a longitudinal direction;
a gate insulating film;
a gate electrode disposed on the gate insulating film in the trench;
a source electrode electrically coupled with the source region and the base region; and
a drain electrode disposed on a back side of the substrate,
wherein the inversion type semiconductor switching element is configured to flow current between the source electrode and the drain electrode via the source region, an inversion type channel region and the drift layer,
wherein the inversion type channel region is provided in a portion of the base region positioned on a side of the trench by controlling a voltage applied to the gate electrode,
wherein the inversion type semiconductor switching element further includes: a plurality of deep layers having the second conductivity type,
wherein each deep layer is disposed in an upper portion of the drift layer below the base region, has a depth deeper than the trench, and extends along a second direction, which crosses the first direction,
wherein each deep layer has an upper portion and a lower portion,
wherein a width of the upper portion is narrower than the lower portion,
wherein the inversion type semiconductor switching element further includes a current diffusion layer having the first conductivity type,
wherein the current diffusion layer is disposed in the drift layer between the plurality of deep layers,
wherein the current diffusion layer has an impurity concentration higher than the drift layer, which is located below the deeper layer,
wherein the current diffusion layer has an impurity concentration distribution in a depth direction, and
wherein the impurity concentration of the current diffusion layer increases as a depth of the current diffusion layer is made shallow.

2. The silicon carbide semiconductor device according to claim 1,
wherein a width of each deep layer decreases in a stepwise manner as a depth of the deep layer gets shallow.

3. The silicon carbide semiconductor device according to claim 1,
wherein a width of each deep layer decreases gradually as a depth of the deep layer gets shallow.

4. (canceled)

5. The silicon carbide semiconductor device according to claim 4, wherein a bottom of the trench is deeper than the current diffusion layer.

6. (canceled)

7. A method for manufacturing a silicon carbide semiconductor device comprising:
forming a drift layer on a substrate, wherein the substrate is made of silicon carbide and has a first or second conductivity type, and the drift layer is made of silicon carbide, has the first conductivity type, and has an impurity concentration lower than the substrate;
forming a plurality of deep layers having the second conductivity type in a surface portion of the drift layer by implanting an ion on a surface of the drift layer through a first mask after the first mask is formed on the surface of the drift layer;
forming a base region having the second conductivity type and made of silicon carbide on the deep layers and the drift layer;
forming a source region in a surface portion of the base region by implanting a first conductivity type impurity on a surface of the base region, wherein the source region has an impurity concentration higher than the drift layer, having the first conductivity type, and made of silicon carbide;
forming a contact region in another surface portion of the base region by implanting a second conductivity type impurity on the surface of the base region, wherein the contact region has an impurity concentration higher than the base region, having the second conductivity type, and made of silicon carbide;
forming a trench on a surface of the source region to penetrate the base region and to reach the drift layer, wherein the trench is shallower than each deep layer, and has a first direction as a longitudinal direction;
forming a gate insulating film on an inner wall of the trench;
forming a gate electrode in the trench;
forming a source electrode to be electrically coupled with the base region via the source region and the contact region; and
forming a drain electrode on a back side of the substrate,
wherein each deep layer is disposed in an upper portion of the drift layer below the base region, has a depth deeper than the trench, and extends along a second direction, which crosses the first direction,
wherein each deep layer has an upper portion and a lower portion, wherein a width of the upper portion is smaller than the lower portion,
the method further comprising:
forming a current diffusion layer having the first conductivity type in the drift layer between the plurality of deep layers,
wherein the current diffusion layer has an impurity concentration higher than the drift layer, which is located below the deeper layer,
wherein the current diffusion layer has an impurity concentration distribution in a depth direction, and
wherein the impurity concentration of the current diffusion layer increases as a depth of the current diffusion layer is made shallow.

8. The method for manufacturing the silicon carbide semiconductor device according to claim 7,
wherein the forming of the deep layers includes:
forming a second mask on the surface of the drift layer;
partially opening the second mask;
implanting a second conductivity type impurity on the surface of the drift layer through the second mask to form a first region of each deep layer;
forming a third mask on the surface of the drift layer;
partially opening the third mask; and
implanting a second conductivity type impurity on the surface of the drift layer through the third mask to form a second region of each deep layer, wherein the second region is located above the first region, and
wherein a width of the second region is smaller than the first region.

9. The method for manufacturing the silicon carbide semiconductor device according to claim 7,
wherein the forming of the deep layers includes:
forming a third mask on the surface of the drift layer;
partially opening the third mask;
implanting a second conductivity type impurity on the surface of the drift layer through the third mask to form a second region of each deep layer;
expanding an opening of the third mask so that a second mask having an opening corresponding to a first region of each deep layer is formed; and
implanting a second conductivity type impurity on the surface of the drift layer through the second mask to form the first region of each deep layer,
wherein the second region is located above the first region, and
wherein a width of the second region is smaller than the first region.

10. The method for manufacturing the silicon carbide semiconductor device according to claim 8,
wherein the implanting of the second conductivity type impurity to form the first region of each deep layer is performed after the forming of the drift layer and before the forming of the current diffusion layer so that the first region of each deep layer is embedded in the drift layer, and
wherein the implanting of the second conductivity type impurity to form the second region of each deep layer is performed after the forming of the current diffusion layer so that the second region of each deep layer is embedded in the current diffusion layer.
